(19) United States
(12) Patent Application Publication
(10) Pub. No.: US 2013/0186451 A1
(43) Pub. Date: Jul. 25, 2013

(54) Off-angle Tracker

(71) Applicants: Nathaniel Tanti, Hillsdale (CA); Rafael Kleiman, Hamilton (CA)

(72) Inventors: Nathaniel Tanti, Hillsdale (CA); Rafael Kleiman, Hamilton (CA)

(21) Appl. No.: 13/747,891

(22) Filed: Jan. 23, 2013

Related U.S. Application Data
(60) Provisional application No. 61/589,967, filed on Jan. 24, 2012.

(51) Int. Cl. H01L 31/052

(52) U.S. Cl. CPC H01L 31/0522
USPC 136/246

(57) ABSTRACT

The present invention is a light tracking collector comprising, an optical module which is configured to rotate about a tilt axis so that a spin axis of the optical module maintains a fixed angle with respect to incident light. Furthermore, the optical module is configured such that incident light that is at a fixed angle with respect to the spin axis will be transformed into converging light that is incident upon a receiver. In a preferred aspect of the present invention, the receiver is a photovoltaic cell and the module is mounted unto a building, or any other suitable man made structure.

### CROSS-REFERENCE TO RELATED APPLICATION

This application is a continuation of U.S. patent application No. 61/589,967, filed Jan. 24, 2012 which is incorporated herein in its entirety by reference.

### FIELD OF THE INVENTION

The present invention relates to a system and method for tracking and collecting light, and then focusing it on a receiver.

### BACKGROUND OF THE INVENTION

Concentrator photovoltaic (CPV) technology refers to any technology that uses optics to focus sunlight onto a photovoltaic cell. There are numerous tradeoffs made when designing CPV systems for high and low concentrations. At about 1×-2× concentration, no tracker need be utilized. From about 2×-300× it is necessary to use single axis trackers. Concentrations beyond that require two axis trackers with increasingly more stringent tracking requirements as the concentration increases.

CPV systems which use concentrator optics to focus sunlight onto a very efficient solar cell with an area of about 1 cm² down to a few mm², with a concentration ratio of about 300-1000×, are often referred to as high concentration photovoltaic (HCPV) systems. For cell areas significantly larger than a few mm², thermal management becomes a significant issue and active cooling methods are necessary. In practice, the optics will only focus light onto the cell efficiently if two axis trackers are used to align the optics with the sun with an accuracy of about 1°. Such accuracy is a tall order when both cost and mechanical stability are issues.

Although geometric optics is over 100 years old it is still evolving into new branches which are being used to optimally design concentrators. The field is called nonimaging optics and one of the first applications was in optimizing sensitive detectors in particle physics around 30 years ago.

Technologies such as silicon photovoltaics gained initial market largely through niche rooftop applications and subsequently through utility scale applications which arose out of falling cell costs due to advances in technology and government support. However, the efficiency of silicon photovoltaic technology has pretty much peaked and only newer cell architectures using different, usually more expensive materials will be able to surpass the performance of silicon photovoltaics. If these new cells are more expensive per unit area, they will require optics to concentrate light, such as the ones found in HCPV systems, and the system as a whole will be less expensive than silicon photovoltaics.

Although it can be debatable whether HCPV systems are also too complex in general, it is very obvious that it is too complex to place current HCPV systems onto rooftops.

This limitation can, in general, may be explained by the fact that conventional two axis trackers move an array of optical modules in three dimensions. To illustrate a point, the cost of an HCPV system can be separated into the cost of the array of optical modules, which scales with area, and the added cost of the two axis tracker. The array of optical modules only scales in area. So, for a conventional two axis tracker, the area will scale by a factor of R² but the volume required for full range of motion will scale by R³. Since it is desirable to use as few trackers as possible, it is obvious that the arrays be made as large as practically possible. However, this means the systems occupies a very large volume and cannot go onto rooftops. To reduce the volume each tracker system occupies, many small trackers must be used which inevitably leads to an increase in complexity and total cost.

Prior art uses either a “bulky” tracking method, as described in the preceding paragraph, methods which try to eliminate the burden of these external trackers by adding more degrees of freedom then physically required, and methods that require an inefficient optical design.

(Campbell & Machado 2010) use two concentrators that rotate independently about the same axis of rotation in a way similar to the way Risley prisms rotate on the same axis, often to steer laser beams. In this case the concentrators both concentrate and steer light towards a receiver.

(Bijl & Peter 2007) use a similar method for tracking as (Campbell & Machado 2010) but with a catadioptric optical system.

(Tomonori et al. 1998) describes of method of moving a receiver laterally within a plane so that as the sun moves across the sky, the cell follows the changing position of the focused image.

(Duerr et al. 2011) describes integrated concentrator and tracking system which moves both the receiver and lenses laterally within a plane which, as in (Tomonori et al. 1998), has some advantageous, but it still requires more degrees of freedom than required to always track the sun's motion in sky. There is only a brief mention of the use of lateral tracking in combination with single axis tracking, which (Duerr 2011) elaborates on.

(Kotsidas et al. 2011) and (Gordon et al. n.d.) describes a system where GRIN optics are moved by a small amount along the x, y, and z axis in order to bring an array of them to focus light onto an array of receivers. Again, there are more degrees of freedom than necessary.

(Tomlinson 2011) describes a method of positioning a plurality of concentrator modules which focus light onto a receiver in a way that allows for the system as a whole to maintain a low profile on a rooftop.

(Brunotte et al. 1996) describes a method that utilizes a one-axis tracker to follow the diurnal movement of the sun and achieve to make use of the limited divergence of the sun's seasonal motion to concentrate

(Winston & Zhang 2012) describes a tracking receiver that utilizes a hemispherical mirror.

(Kritchman n.d.) describes a fixed, linear convex Fresnel lens with a moving receiver to track the sun as it moves across the sky. Unfortunately, the sun moves over a large portion of the sky and due to a lack of symmetry in the system, large aberrations are inevitable when the sun is a certain positions.

(Bachmaier et al. n.d.) describes a method of making fine adjustments to the receiver to compensate for misalignment in the optical system.

(Ford et al. n.d.) describes a method of capturing lighted using a dimpled planar waveguide. The dimples serve as lenses which focus the beam onto a facet which steers the light to become coupled into the light guide. It is possible to move all of these facets laterally so that the sun may be focused over a wide range of angles. As with all waveguides, there are absorption issues altering the solar spectrum and possibly having adverse affects on the performance of the solar cell. The lack of symmetry through the course of the year also reduces the ultimate concentration ratio that can be achieved.

(Baker et al. 2012) proposes the use of active materials which allow the index of refraction to change in such a way that can replace the mechanical motion of a tracking system. However, such designs are only concepts that have yet to be proven commercially viable.

(Sweatt et al. 2010) propose a system in which a coarse external tracker is used in combination with optics which moves laterally within a plane as fine adjustment. The idea is that this combination of coarse tracking and fine adjustment will have an overall lower system cost. On the other hand, this system introduces more degrees of dynamic freedom than required, and the use of lateral motion will not increase the thermodynamic efficiency beyond what can be achieved with static optics.

### REFERENCES

Bachmaier, G. et al., PASSIVE FINE-ADJUSTMENT CONCEPT FOR CPV PLANTS.
Baker, K. A. et al., 2012. Reactive self-tracking solar concentrators: concept, design, and initial materials characterization. Applied Optics, 51(8), pp. 1086-1094.
Bijl, Ro. & Peter, P., 2007. Device For Converting Solar Energy.
Brunotte, M., Goetzberger, A. & Blieske, U., 1996. Two-stage concentrator permitting concentration factors up to 300× with one-axis tracking. Solar Energy, 56(3), pp. 285-300.
Campbell, R. O. & Machado, M., 2010. Tracking Concentrator Employing Inverted Off-Axis Optics and Method.
Duerr, F., 2011. Free form optics for a linear field of view.
Duerr, F., Meuret, Y. & Thienpont, H., 2011. Tracking integration in concentrating photovoltaics using laterally moving optics. Optics Express, 19(S3), pp.A207-A218.
Ford, J. E. et al., System and Method for solar energy capture and related method of manufacturing.
Gordon, J. M., Kotsidas, P. & Modi, V., Spherical Gradient Index (GRIN) Lenses and their uses in Solar Concentration.
Kotsidas, P., Modi, V. & Gordon, J. M., 2011. Nominally stationary high-concentration solar optics by gradient-index lenses. Optics Express, 19(3), pp. 2325-2334.
Kritchman, E. M., A fixed Fresnel lens with tracking collector. Solar Energy, 27(1), pp. 13-17.
Sweatt, W. C. et al., 2010. Micro-optics for high-efficiency optical performance and simplified tracking for concentrated photovoltaics (CPV). In Society of Photo-Optical Instrumentation Engineers (SPIE) Conference Series. p. 34. Available at: http://adsabs.harvard.edu/abs/2010SPIE.7652E.34S [Accessed Aug. 19, 2011].
Tomlinson, A., 2011. OFFSET CONCENTRATOR OPTIC FOR CONCENTRATED PHOTOVOLTAIC SYSTEMS.
Tomonori, N., Kyoichi, T. & Kouetsu, H., 1998. Light Converging Solar Module.
Winston, R. & Zhang, W., 2012. LOW COST HIGH EFFICIENCY SOLAR CONCENTRATOR WITH TRACKING RECEIVERS.

### SUMMARY OF THE INVENTION

It should be appreciated that this summary is provided to introduce a selection of concepts in a simplified form, the concepts being further described below in the detailed description. The summary is not intended to identify key features or essential features of this disclosure, nor is it intended to limit the scope of the disclosure.

The objective of the present invention is to provide an improvement upon current technology used to capture and concentrate light from a source unto a receiver. Although it is no way meant to be limiting, the description of the invention will place particular emphasis on when the source is the sun and the receiver is a photovoltaic cell.

The invention is a light tracking collector comprising, an optical module which is configured to rotate about a tilt axis so that a spin axis of the optical module maintains a fixed angle with respect to incident light. Furthermore, the optical module is configured such that incident light that is at a fixed angle with respect to the spin axis will be transformed into converging light that is incident upon a receiver.

### BRIEF DESCRIPTION OF THE DRAWINGS

FIG. 1—An isometric view of a module (100)a in the dual freeform mirror embodiment.

FIG. 2—Side view of module (100)a which more clearly illustrates the tilt axis (1030)a which is concentric with the pivot (120)a and the cross-section cut MM.

FIG. 3—Illustrates the cross section MM as given in FIG. 2, highlighting the relative position of adjacent spin axis (1040)a.

FIG. 4—A more detailed view of a single optical module (1000)a from FIG. 3.

FIG. 5—Another perspective of the optical module (1000)a to more clearly define the path that incident light is intended to follow.

FIG. 6—An overhead view of the module (100)b for the flat receiver single lens embodiment.

FIG. 7—Cross section AA from FIG. 6.

FIG. 8—Detailed view of a single optical module (1000)b from FIG. 7.

FIG. 9—View of optical module (1000)c.

FIG. 10—Detailed view of optical module (1000)c.

FIG. 11—Isometric view of module (100)e.

FIG. 12—Isometric view of a single optical module (1000)e.

FIG. 13—Side view of the optical module (1000)e.

FIG. 14—An isometric view of a louvered system (5000)d.

FIG. 15—Illustration of the collector reference frame with respect to a Earth surface reference frame.

FIG. 16—Trimetric view of the collector plane reference frame with respect to the collector reference frame.

FIG. 17—Diametric view of a single axis tracker in the on-axis tracking configuration.

FIG. 18—Isometric view of the projection of S in the collector plane reference system when a the phase ψ is added to the hour angle δ to achieve one of the off-angle tracking configurations.

FIG. 19—Isometric view of the projection of S in the collector plane reference system when the phase ψ is subtracted from the hour angle β to achieve another one of the off-angle tracking configurations.

FIG. 20—Diametric view of a single axis tracker with the diurnal motion phase shifted by +ψ to satisfy the off angle tracking requirements.

FIG. 21—Diametric view of a single axis tracker with the diurnal motion phase shifted by −ψ to satisfy the off angle tracking requirements.

### DETAILED DESCRIPTION

In the following description, the use of “a”, “an”, or “the” can refer to the plural. We describe here a series of examples intended only to make the scope of the invention clear and are not to be interpreted as limiting the disclosure. It will be appreciated by those skilled in the art that there are a wide variety of optical components and mechanical components which aren't explicitly stated, but yet still can be configured in a way that results in a system falling within the scope of the described invention.

Specific examples given throughout the discussion presented here are only intended to enable those skilled in the art. They are in no way limiting the scope of the present invention.

### Dual Freeform Mirror Embodiment

### General Module

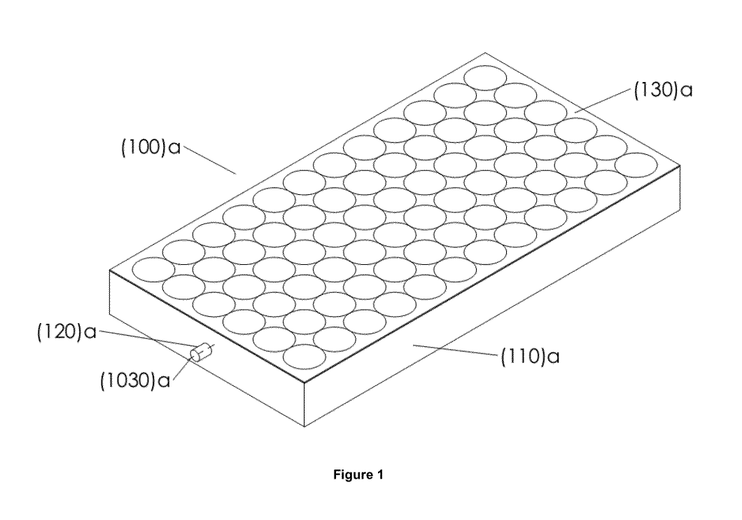

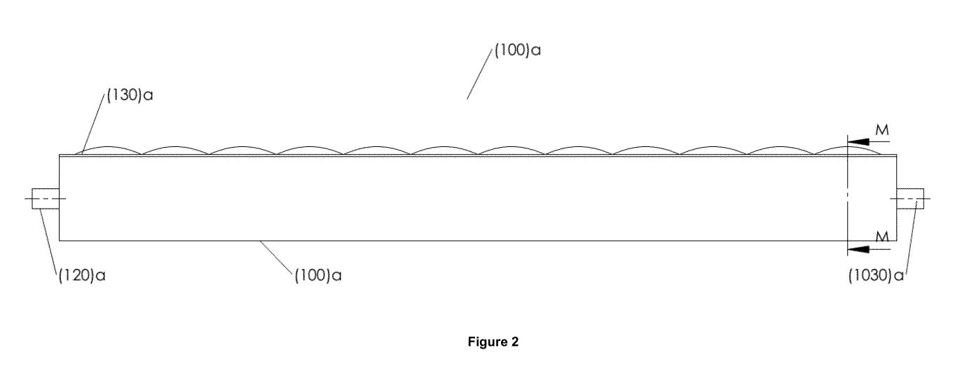

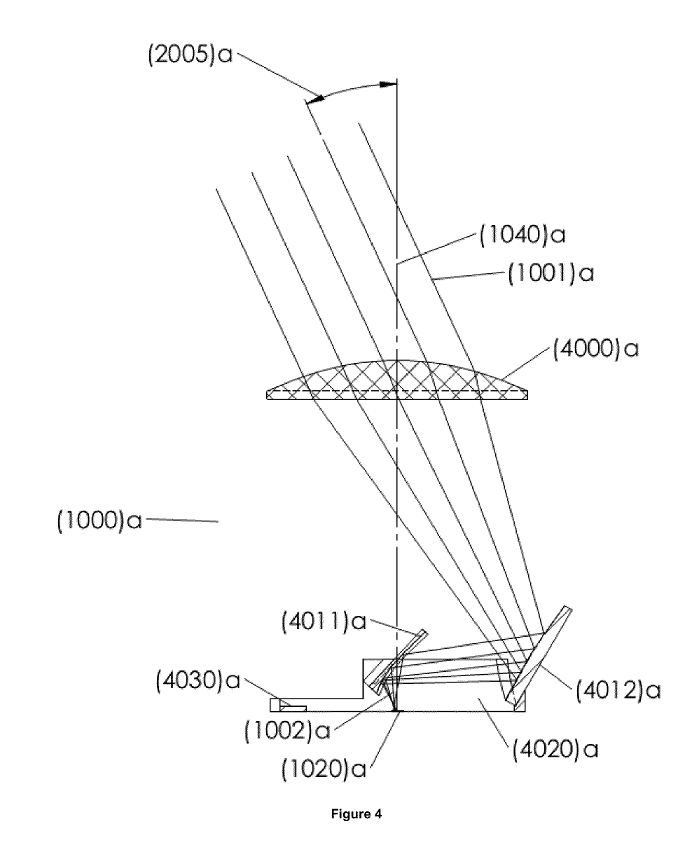

Referring to FIG. 1 to FIG. 4, we have a module (100)a comprising, a module box (110)a, a pivot (120)a to allow rotation of the module (100)a about a tilt axis (1030)a, an array of one or more identical optical modules (1000)a positioned within the interior of the module box (110)a to collect incident light (1001)a, and an actuator (4030)a to align the one or more optical modules (1000)a for a given orientation of the module (100)a about the tilt axis (1030)a, where the actuator (4030)a is preferably positioned as close to the outer circumference of the rotatable mount (4020)a as possible as opposed to placing the actuator (4030)a closer to the spin axis (1040)a where there will be less leverage.

### Optical Module Construction

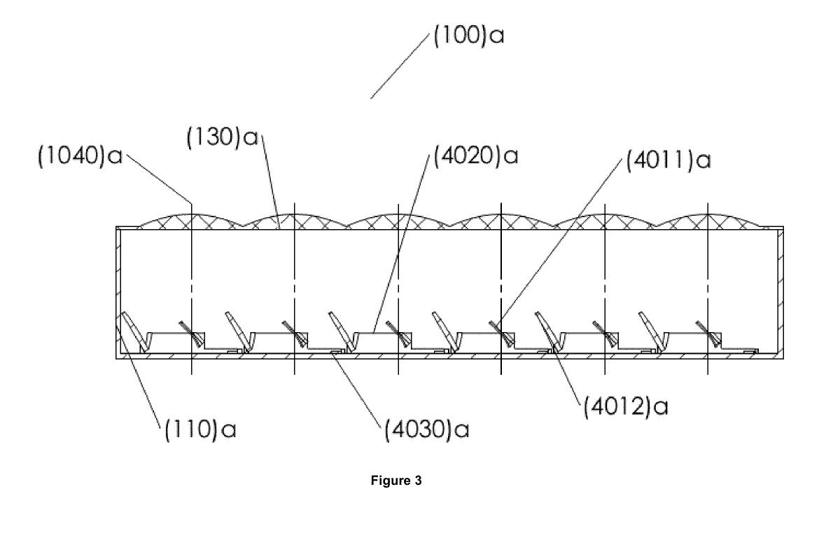

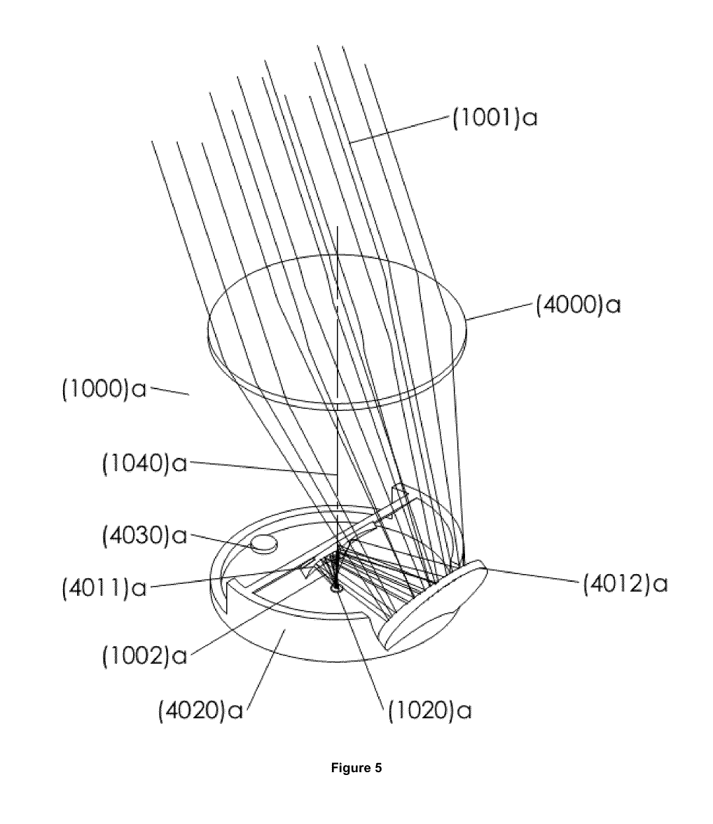

Referring to FIG. 3 to FIG. 5, the optical module (1000)a may comprise, the lens (4000)a, positioned so it has a curvature with rotational symmetry about a spin axis (1040)a, an inner mirror (4011)a and an outer mirror (4012)a which are positioned rotatably about the spin axis (1040)a by fixing them to a rotatable mount (4020)a, and the rotatable mount (4020)a may be attached rotatably about the spin axis (1040)a onto the module box (110)a, and a receiver (1020)a may be attached to the module box (110)a so that it is both centered on the spin axis (1040)a, and it is substantially perpendicular the spin axis (1040)a.

### Means of Spin Axis Rotation

The rotatable mount (4020)a may be placed at some distance from the lens (4000)a, and rotated to some angle about the spin axis (1040)a, such that when incident light (1001)a is at a off angle (2005)a with respect to the spin axis (1040)a, and is impingent on the lens (4000)a, it traverses through and out of the lens (4000)a, and towards the outer mirror (4012)a, and then reflected from the outer mirror (4012)a towards the inner mirror (4011)a, and off of the inner mirror (4011)a as converging light (1002)a, which is impingent on the receiver (1020)a.

### Means of Tilt Axis Rotation

The module box (110)a may be made to rotate on the pivot (120)a so that the one or more optical modules (1000)a within the interior of the module box (110)a may rotate about the tilt axis (1030)a, into one of two configurations, such that the trajectory of the incident light (1001)a is at a off angle (2005)a, with respect to the spin axis (1040)a of the one or more optical modules (1000)a, where the position of the tilt axis (1030)a may not be the same relative to every optical module (1000)a and depends on the exact position of each optical module (1000)a within the module box (110)a, and depends on the position of the pivot (120)a or some other means of rotating the module (100)a about the tilt axis (1030)a.

### Dual Freeform Mirror Embodiment Discussion

Referring to the dual freeform mirror embodiment, as illustrated in FIG. 1 to FIG. 5, the optical module (1000)a may have four optical surfaces; two refractive surfaces and two mirrored surfaces. It is well known to those skilled in the art that it may be possible with four surfaces to not have light losses from scattering and absorption that are substantially greater than that of a typical concentrator photovoltaic module.

The lens (4000)a may be an aspheric-plano lens, and the inner mirror (4011)a and outer mirror (4012)a are small freeform surfaces with symmetry about the meridional plane of the lens (4000)a. The lens (4000)a, the lens array (130)a, the inner mirror (4011)a, and the outer mirror (4012)a may all be manufactured on the large scale.

In the freeform mirror embodiment, the lens (4000)a serves to focus the incident light (1001)a down to a sufficiently small area so that the inner mirror (4011)a and outer mirror (4012)a used for subsequent concentration can be made a size on the order of a few centimeters or smaller. It may be easier to make small freeform surfaces than larger ones, which is why the size of the inner mirror (4011)a and outer mirror (4012)a are important. In addition, freeform surfaces give more design freedom for transforming the incident light (1001)a into converging light (1002)a incident on the receiver (1020)a. To clarify, only a single deflective surface is required to transform one congruency of rays to another congruency. In general, this deflective surface is a freeform surface. Using two or more freeform deflective surfaces allows for more efficient control in transforming incident light (1001)a into converging light (1002)a impingent on the receiver (1020)a. And with more design freedom, the optical module (1000)a may have a greater acceptance angle and the receiver (1020)a may be illuminated with higher concentration, and higher homogeneity. For clarification, the curvature of the lens (4000)a is equally important as the curvature of the inner mirror (4011)a and the outer mirror (4012)a.

The dual freeform mirror embodiment does not require that the receiver (1020)a and the lens (4000)a move with respect to one another. This may be important if the receiver (1020)a must be fixed to the module box (110)a so that high thermal conductivity is present between the receiver (1020)a and the exterior of the module box (110)a. In addition, the lens (4000)a is also exposed to the external environment. The relative motion of the lens (4000)a and receiver (1020)a may make it more complicated to create an enclosure of the receiver (1020)a away from the external environment. So although the present invention does not exclude embodiments where the relative motion of the lens (4000)a and the receiver (1020)a may be present, it is preferable that it is not present.

Another possible embodiment not shown, may be to replace the outer mirror (4012)a of the dual freeform mirror embodiment with a mirror that is rotationally symmetric about the optical axis, or the spin axis (1040)a that the optical axis is coincident with, and is designed such that the incident light (1001)a will traverse through the lens (4000)a, and onto this mirror that is rotationally symmetric mirror about the spin axis (1040)a, and then towards the inner mirror (4011)a, and then finally from the inner mirror (4011)a as converging light which is impingent onto the receiver (1020)a. In such a case, the mirror that is rotationally symmetric about the spin axis (1040)a may not have to be mounted rotatably, and only the inner mirror (4011)a may have to be mounted rotatably.

Another possible variation of the dual freeform mirror embodiment would be to make the lens (4000)a a spherical gradient index lens.

### Flat Receiver Single Lens Embodiment

### General Module

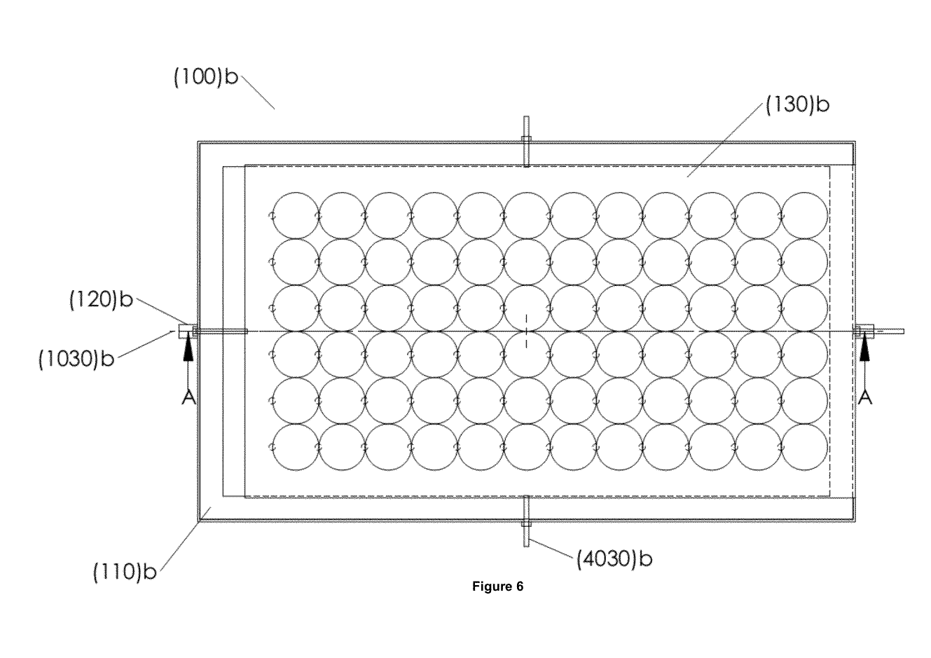

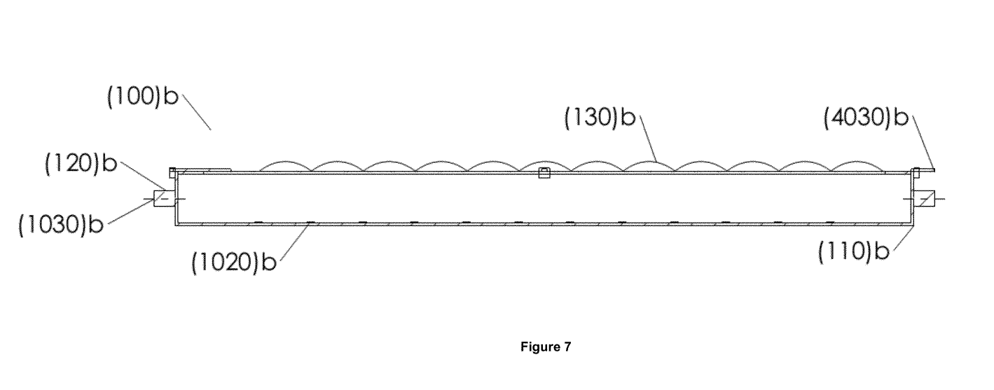

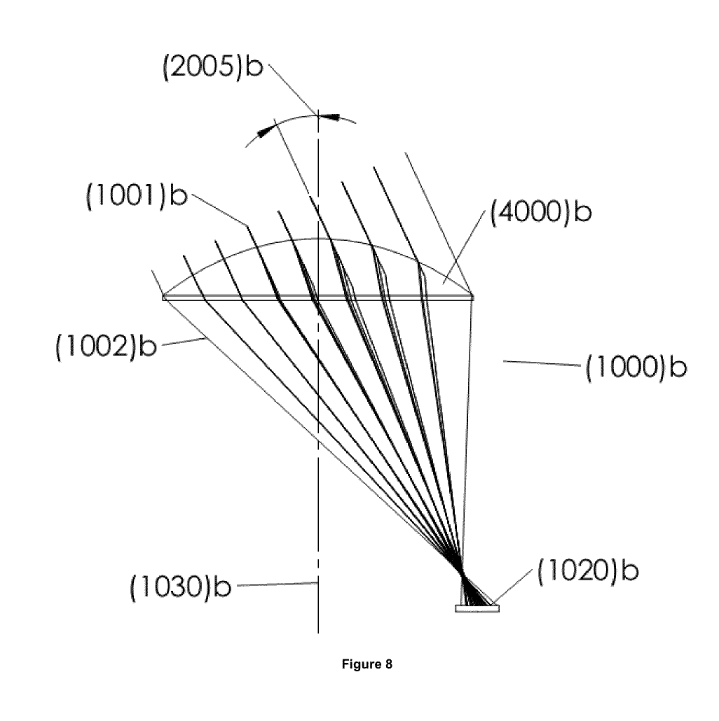

Referring to FIG. 6 to FIG. 8, we have a module (100)b comprising, a module box (110)b, a pivot (120)b to allow rotation of the module box (110)b about a tilt axis (1030)b, an array of one or more identical optical modules (1000)b positioned within the interior of the module box (110)b to collect incident light (1001)b, and an actuator (4030)b to align one or more optical modules (1000)b for a given orientation of the module (100)b about the tilt axis (1030)b.

### Optical Module Construction

The optical module (1000)b comprises, the lens (4000)b, positioned so it has a curvature with rotational symmetry about a spin axis (1030)b, and a receiver (1020)b which may be mounted to the module box (110)b at some distance from the lens (4000)b, and from the axis of rotational symmetry of the lens (4000)b, and so that the normal of the receiver (1020)b remains substantially parallel to the spin axis (1030)b.

### Means of Spin-Axis Rotation

Each lens (4000)b, which may be part of a larger lens array (130)b, may be mounted to the module box (110)b such that it still may move freely in a direction perpendicular to the spin axis (1030)b, but preferably not rotate with respect to the module box (110)b.

The movement of the lens (4000)b or lens array (130)b may be such that every receiver (1020)b is moved in an arc around the spin axis (1030)b of every corresponding lens (4000)b, such that when incident light (1001)b is at a off angle (2005)b with respect to the spin axis (1030)b, and is impingent on the lens (4000)b, it traverses through the lens (4000)b, and then out the lens (4000)b as converging light (1002)b, which is impingent on the receiver (1020)b.

### Tilt Axis Rotation

The module box (110)b may be made to rotate on the pivot (120)b so that the one or more optical modules (1000)b rotate about the tilt axis (1030)b, into one of two configurations, such that the trajectory of the incident light (1001)b is at a off angle (2005)b, with respect to the spin axis (1030)b of the one or more optical modules (1000)b, where the position of the tilt axis (1030)b may not be the same relative to every optical module (1000)b and depends on the exact position of each optical module (1000)b within the module box (110)b, and depends on the position of the pivot (120)b or some other means of rotating the module (100)b about the tilt axis (1030)b.

### Tilted Receiver Embodiment

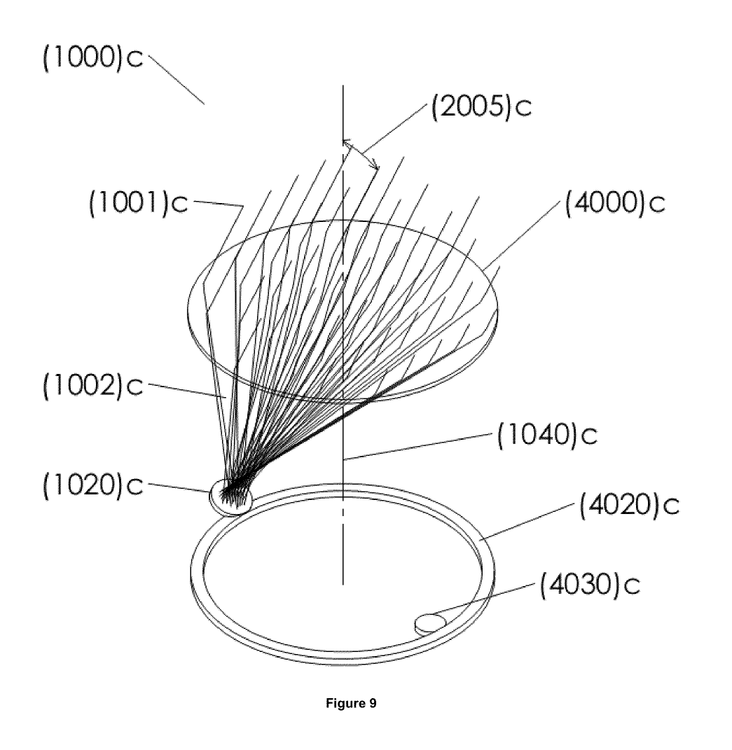

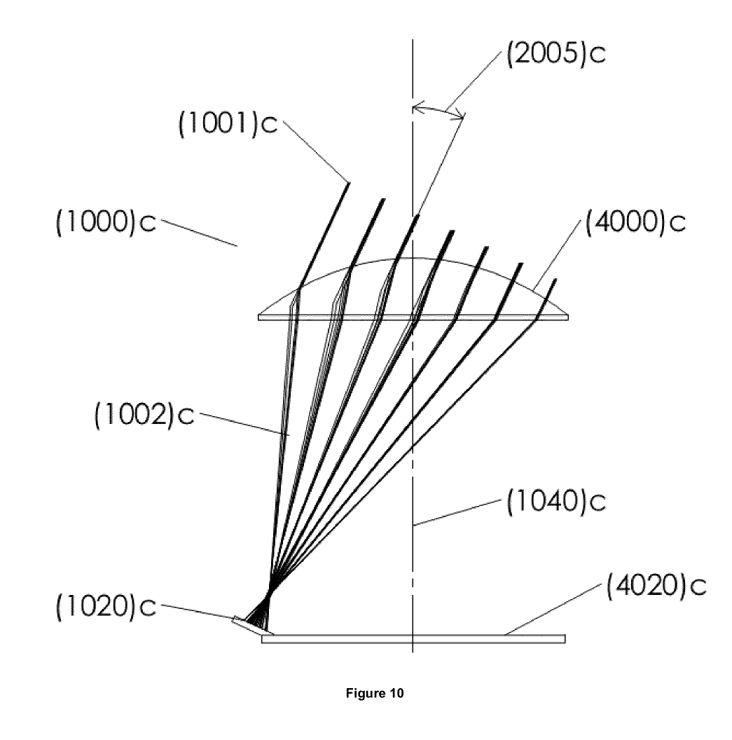

In yet another embodiment, referred to as the tilted receiver embodiment, and is seen in FIG. 9 and FIG. 10, we have a optical module (1000)c, which is a variation of the optical module (1000)a of the dual freeform lens embodiment, wherein the lens (4000)a, the rotatable mount (4020)a, the actuator (4030)a, the outer mirror (4012)a, the inner mirror (4011)a, and the receiver (1020)a, are replaced by, the lens (4000)c, positioned so it has a curvature with rotational symmetry about the spin axis (1040)c, a receiver (1020)c that is fixed to a rotatable mount (4020)c so that it may move rotatably about the spin axis (1040)c and so that the normal of the receiver (1020)c remains substantially centered within the intensity distribution of the converging light (1002)c, and the rotatable mount (4020)c may be attached rotatably about the spin axis (1040)c on to the module box (110)c.

### Means of Spin Axis Rotation

The rotatable mount (4020)c may be placed some distance from the lens (4000)c, and rotated to some angle about the spin axis (1040)c, such that when incident light (1001)c is at a off angle (2005)c with respect to the spin axis (1040)c, and is impingent on the lens (4000)c, it traverses through and out the lens (4000)c as converging light (1002)c which is impingent on the receiver (1020)c.

### Dual Lens Embodiment

### General Module

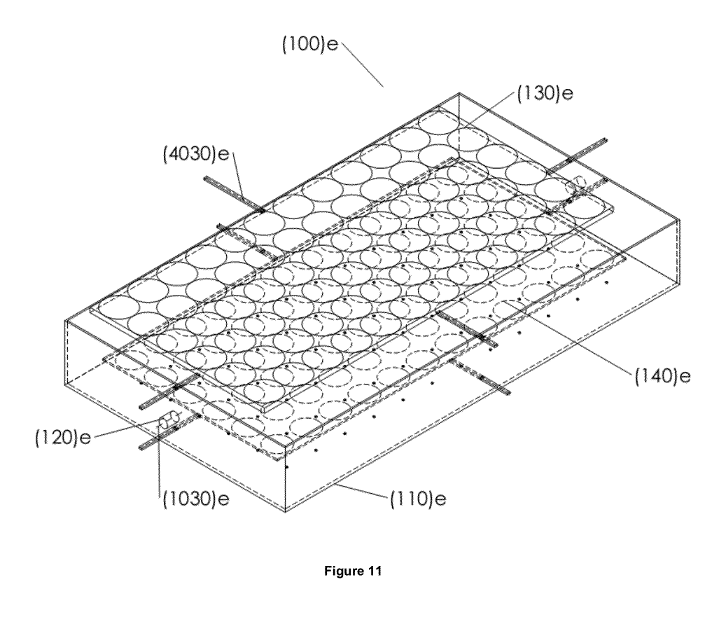

Referring to FIG. 11, we have a module (100)e comprising, a module box (110)e, a pivot (120)e to allow rotation of the module (100)e about a tilt axis (1030)e, an array of one or more identical optical modules (1000)e positioned within the interior of the module box (110)e to collect incident light (1001)e, and one or more actuators (4030)e to align the one or more optical modules (1000)e for a given orientation of the module (100)e about the tilt axis (1030)e.

### Optical Module Construction

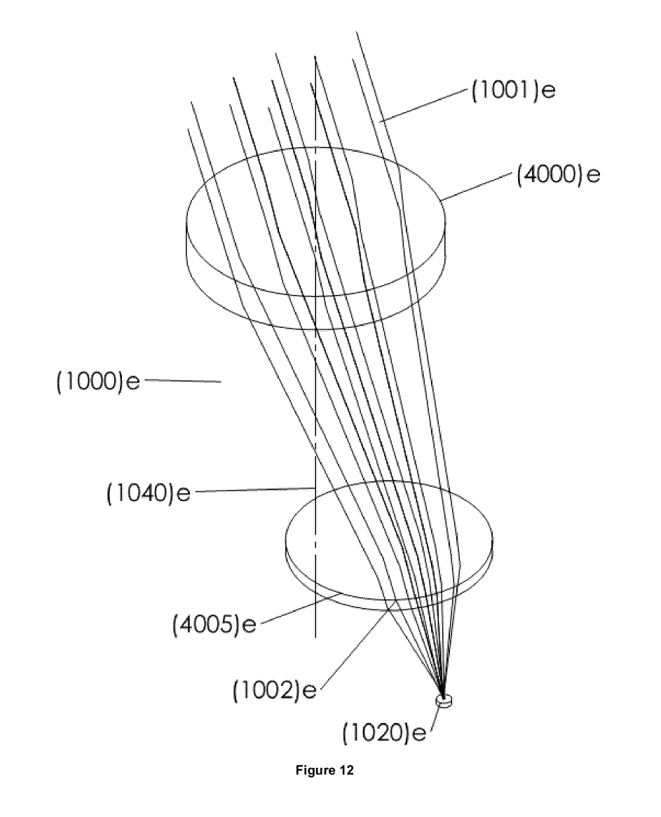

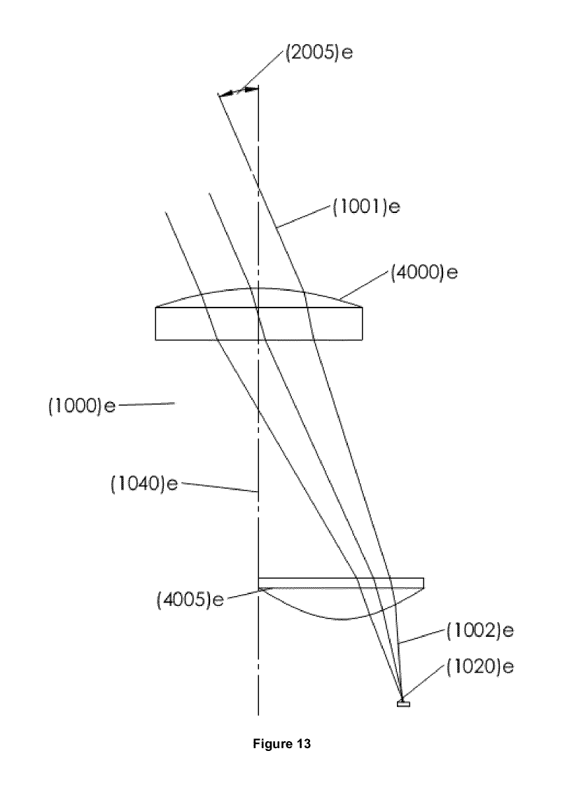

Referring to FIG. 11 to FIG. 13, the optical module (1000)e may comprise, the lens (4000)e, positioned so it has a curvature with rotational symmetry about a spin axis (1040)e, a second lens (4005)e with curvature that is rotationally symmetric about its optical axis, and the optical axis is parallel with, but may not be coincident with the spin axis (1040)e, and a receiver (1020)e placed away from the spin axis (1040)e but oriented so is remains substantially perpendicular to the spin axis (1040)e.

### Means of Spin Axis Rotation

The lens (4000)e, which may be part of a lens array (130)e, and the second lens (4005)e, which may be part of a second lens array (140)e, may be moved by one or more actuators (4030)e, such that the lens (4000)e and second lens (4005)e may only move in directions substantially perpendicular to the spin axis (1040)e, and such that both the receiver (1020)e and the second lens (4005)e move in circular motions about the spin axis (1040)e which is coincident with the optical axis of the lens (4000)e, and such that when incident light (1001)e is at an off angle (2005)e with respect to the spin axis (1040)e, and is impingent on the lens (4000)e, it traverses through and out of the lens (4000)e, and towards the second lens (4005)e, and through and out of the second lens (4005)e, and towards the receiver (1020)e as converging light (1002)e.

### Means of Tilt Axis Rotation

The module box (110)e may be made to rotate on the pivot (120)e so that the one or more optical modules (1000)e rotate about the tilt axis (1030)e, into one of two configurations, such that the trajectory of the incident light (1001)e is at an off angle (2005)e, with respect to the spin axis (1040)e of the one or more optical modules (1000)e, where the position of the tilt axis (1030)e may not be the same relative to every optical module (1000)e and depends on the exact position of each optical module (1000)e within the module box (110)e, and depends on the position of the pivot (120)e or some other means of rotating the module (100)e about the tilt axis (1030)e.

### Secondary Optic Embodiments

In any embodiment, it is possible to improve the optical performance of the system with the introduction of another optical component, often referred to as secondary optics to those skilled in the art. These optical components may include, but aren't limited to, refractive optics which may be optically coupled to the receiver, such as tapered rectangle prisms, refractive compound parabolic concentrator prisms, compound elliptical concentrators, refractive domes, freeform optics, ball lenses, and gradient index optics. The secondary optical components may also be reflective, such as compound parabolic concentrators, compound elliptical concentrators, and different types of freeform optics.

Within the dual freeform lens embodiment, the inner mirror (4011)a and outer mirror (4012)a are manufactured to have surfaces that only have symmetry about the meridional plane of the lens (4000)a, which they intersect. The surfaces they possess are generally known to those skilled in the art as free form surfaces. Such surfaces may be manufactured using modern free form surface machining methods, such as slow servo and fast servo diamond turning. The surfaces may be manufactured directly, or more preferably, the surfaces may be machined into a master mold which can then be used to manufacture a plurality of optical components with the same free form surface. Methods that involve the use of a mold may include compression molding for glass, thermal slumping, and injection molding.

If the optics are made of non reflective materials, they may be made reflective, if required, by a process such as electroless nickel plating, evaporated aluminum, or any other suitable process.

The absence of optical coupling between some optical component and some receiver may be desirable in order to mitigate performance degradation from undesired separation between optical components. However, it is well within the scope of this invention to use optical coupling when suitable.

### Different Primary Lens Embodiments

The lens (4000)b of the flat receiver single lens embodiment, or any suitable optical component of any embodiment, may be replaced by a gradient index optic (GRIN) lens, which may also have spherical symmetry such as a Luneberg lens. However, given the practical limitations of the Luneburg lens, other designs well known to those skilled in the art may use a continuous change in the index of refraction in combination with a discontinuous change in the index of refraction.

A spherical GRIN lens may also be tapered so that a plurality of GRIN lenses may fit tightly within a lens array. The GRIN lens is may be preferable from a technical standpoint since only one optical element is required to focus incident light effectively onto some receiver. The GRIN lens may be implemented in a variety of different ways, similar to the embodiments already discussed. For example, some receiver may rotate about axis of symmetry of the GRIN lens such that the receiver always remains at the focal point of the GRIN lens, and the normal of that receiver is always substantially centered about the intensity distribution at the GRIN lens focal point. Another example may be the same, but the receiver has its normal remain parallel to the axis of symmetry about which the receiver rotates. If the cost to manufacture GRIN lenses is reduced, it may be preferable to use them.

The lens (4000)b of the flat receiver single lens embodiment, or any other embodiment with a lens, may be replaced by a lens with two curved surfaces which are rotationally symmetric about the same axis, and who's shape is sometimes referred to as a meniscus. The curved surface maybe, but isn't limited to conic sections, or any other aspheric curve.

### Other Variations

### Lens Array

The lens array (130)a, as in the dual freeform mirror embodiment, may comprise an array of one or more lenses (4000) molded into a single solid, transparent substrate, where the substrate may preferably made of glass, or where the substrate may preferably made of a plastic such as acrylic or PMMA, or the substrate may be any other suitable transparent material. The different types of materials that can be used for the lens array (130)a may also be used within a lens array of any other embodiment, or as part of any other suitable optical component of any other possible embodiment.

The lens array (130)a of the dual freeform mirror embodiment may be fixed to the module box (110)a to create an enclosure, which may also be hermetically sealed against the ambient environment.

In another preferred embodiment, the perimeter of one or more lenses in a lens array is not limited to be rotational symmetric but may also tapered so that it tiles more effectively with identical, adjacent lenses. Such shapes include but are not limited to triangular, a hexagon or a square.

### Concentration Ratio

It is well known to those skilled in the art that the desired ratio between the average irradiance on the receiver and the average irradiance on the optical module aperture should be on the order of ten to one hundred, or one hundred to five hundred, or five hundred to one thousand, or one thousand to two thousand.

### Module Box

It is also well known to those skilled in the art that the depth of the module box must be as small as possible, preferably no more than 30 centimeters and no less than half a centimeter.

It is well known to those skilled in the art that the most economically viable size for a photovoltaic module is such that under the industries standard test conditions, it must produce around 50W-200W. It is preferable that the size of the module box in the present invention meet the same industry standard. It is also preferable that the module box be tailored to be larger or smaller to meet the demands for niche market applications.

The module box of any embodiment of the present invention may be made of a material such as a suitable glass, or of steel, or of galvanized steel, or of aluminum, or of any suitable metal, or of any suitable plastic.

The module box of any embodiment of the present invention may take on a variety of shapes including, but not limited to a rectangular prism, a cube, a rectangular prism with fillets or tapers along the edges, a cylinder, or any other geometric shape.

### Thermal Management

It is well known to those skilled in the art that a photovoltaic cell with a size substantially larger than a few centimeters square and under a concentration of about one hundred suns or higher will require active thermal management.

It is also well known to those skilled in the art that a photovoltaic cell about only 1 cm² or smaller in area will not require active thermal management.

It is also known to those skilled in the art that a photovoltaic cell close to 1 mm² in area and under a concentration of about one hundred suns or higher will dissipate heat more readily than a cell closer to 1 cm².

It is also well known to those skilled in the art that using a photovoltaic cell less than 1 cm² in area may enable the minimal use of heat sink material.

It is also well known to those skilled in the art that smaller photovoltaic cells, around 1 cm² or 1 mm², tolerate non uniform illumination more effectively than larger photovoltaic cells and thus are preferable.

It is also well known to those skilled in the art that the preferable operation temperature of a photovoltaic cell is at ambient temperature or room temperature, but no greater than eighty degrees above ambient temperature or room temperature.

In would be preferred that in the case that the receiver is a photovoltaic cell, and the receiver is mounted to the module box, that a thermal contact between the receiver and module box is sufficient to dissipate heat so that the temperature of the photovoltaic cell is within a acceptable operation temperature. It is also preferable that whilst the temperature of the photovoltaic cell remain within acceptable operation temperatures, that the electrical conductivity between the photovoltaic cell and the exterior of the module box remain low so that the exterior of the module box does not pose a threat as a high voltage source which may short unsafely.

Materials with which a thermal contact may be made are copper, aluminum, alumina, or some other suitable material or combination of suitable materials.

### Receiver

The receiver of the various embodiments may be a photovoltaic cell, a receiver for a solar thermal system, an imaging device, a CCD, transparent glass, a fiber optic, a fiber optic with a liquid core, or anything designed to transport light or use light for some useful function. The receiver may also be engineered to reflect, absorb or transmit light of a desired wavelength, and the receiver may also be engineered to reflect, absorb, or transmit light impingent at a desired angle, and the receiver may also take advantage of the principle of reciprocity so that light is transmitted from the receiver along the same path of the impingent light, but in the opposite direction.

It is well known that photovoltaic cells may come in a square shape, or a nearly circular shape, or another shape which may be used in the present invention. The photovoltaic cell may be a silicon cell, a thin film cell, a dye sensitized cell, a multi junction photovoltaic cell, or any other device which uses the photovoltaic effect to convert light into electricity. The size of the photovoltaic cell may be on the order of a 20 cm² in area, down to 1 mm² in area.

### Off Angle

A specific aspect of the present invention is that the off angle may be never zero, and may never be changing during the normal operation period of the present invention.

Although off angle tracking is applicable in many applications, one specific application of interest is solar tracking for concentrator photovoltaic and concentrator thermal systems. When the present invention is oriented such that the tilt axis is parallel with the Earth's axis of rotation, the fact that the maximum extent of the Sun's declination is about 23.44° from the equinox may be exploited by setting the off angle to 23.44°, or within five degrees of 23.44°, or within 10 degrees of 23.44°.

The cosine of 23.44° is about 92, which means that if a surface were to be aligned at an angle of 23.44° with respect to the direction of incident light from the Sun, then the resulting cosine loss would about 8%. For the present invention, this cosine loss is present throughout the entire year. The benefit of the present invention is the resulting rotational symmetry which can be utilized in the design of an optical system which uses an internal tracking system to follow the Sun's seasonal motion. Such optical designs are the ones given by the various embodiments of this invention.

It is well known to those skilled in the art that in order to minimize cosine losses, a conventional tracker will follow the Sun so that the angle between the normal of the collector surface and the incident light from the Sun is minimized. In the case of dual axis trackers, the minimal angle is zero, or as close to zero as practically can be. In the case of single axis trackers, the angle is not always zero, but it is minimized and is also not constant over the course of a year.

Another method of tracking the Sun, well known to those skilled in the art, is referred to as backtracking, where a computer is used to command an array of solar trackers to move so that inter-array shading will be minimized. In this case, the angle between the incident light from the Sun and the normal or the collector is not constant.

A specific aspect of the present invention is that the off angle, which is the angle between the normal of the collector, and the direction of incident light from the Sun, is held at a angle that is not zero, and is not changing, during the normal operation period of the present invention. A normal operation period is well known to those skilled in the art of solar tracking to be the time over which the tracker may track the incident light from the Sun without the presence of intermittent disturbances, such as cloudy weather, high winds, unusual loading due to foreign objects, and other environmental aspects. These circumstances in no way limit the possibility of continuing normal operation but may sometimes impede it. Another possible circumstance is the period over which the present invention configures itself to be in the one of two possible configurations, as discussed in various embodiments.

In the case that the present invention is applied to solar tracking, but is not aligned so that the tilt axis is parallel with the Earth's axis of rotation, then the off angle may be substantially larger or smaller than 23.44°, from 5° to 23.44°, or substantially larger, from 23.44° to 40°.

### Internal Tracking

The present invention is largely characterized by the rotation of one or more optical modules about some tilt axis, and every optical module having a component that may undergo dynamic change causing the asymmetry of the optical module to rotate about the respective spin axis. Symmetry present between one or more optical modules may dictate what methods an actuator may be implemented most effectively.

For example, with the flat receiver single lens embodiment, a plurality of lenses (4000)b within a lens array (130)b undergo synchronous linear motion, but restricted so that every lens (4000)b moves in an arc centered about their respective spin axis (1030)b. There may not need to be a change in the orientation of components within every optical module (1000)b in this case.

Another example is the dual freeform lens embodiment, where there is a single rotatable mount (4020)a for every optical module (1000)a which changes both the position and orientation of the inner mirror (4011)a and the outer mirror (4012)a. Examples of ways in which one or more rotatable mounts (4020)a may rotate about their respective spin axis (1040)a may include using an actuator (4030)a for every rotatable mount (4020)a so that everyone may be rotated independently.

Yet another method by which the rotatable mounts (4020)a may rotate is where gears movably connect adjacent rotatable mounts (4020)a such that the rotation of one rotatable mount (4020)a causes all rotatable mounts (4020)a to rotate in synchronous motion. Yet another method by which the rotatable mounts (4020)a may rotate is where toothed gear slider, or a worm gear, which is movably connected to a plurality of rotatable mounts (4020)a such that the rotation of one rotatable mount (4020)a causes all rotatable mounts (4020)a to rotate in synchronous motion. Yet another method by which the rotatable mounts (4020)a may rotate is where a belt, chain, or some other flexible material or connecter, movably connects a plurality of adjacent rotatable mounts (4020)a such that the rotation of one rotatable mount (4020)a causes all rotatable mounts (4020)a to rotate in synchronous motion. Yet another method by which the rotatable mounts (4020)a may rotate is where every rotatable mount (4020)a has some rotatable joint located away from the spin axis (1040)a, and where the plurality of these joints are connected with rigid connectors, such that the rotation of one rotatable mount (4020)a causes all rotatable mounts (4020)a to rotate in synchronous motion.

The seasonal motion of the sun is very slow, being on the order of 10 per day. The internal tracking system in one preferred embodiment may require that the actuator only move slowly so as to mitigate the cost of using an actuator that would unnecessarily move faster.

The present invention is also known to be able to perform its function in one of two configurations. That is an optical module may go into one of two orientations about the tilt axis, along with being configured into the appropriate orientation about the spin axis. In certain embodiments, it may be preferable to use one of the two possible configurations at one time, and the other configuration at another time. Therefore, it may be preferable to have an actuator which may perform rapid transitions from one configuration to the next. In yet another embodiment, where the receiver is a photovoltaic cell, the rate of transition would be fast enough to mitigate any potential power production disruptions. In yet another embodiment, the optical module would have two actuators and two sets of suitable optical components, each one satisfying one of the two possible configurations at any given time.

In yet another embodiment, an internal tracker would be suitable for both seasonal tracking, and fine adjustments in regards to the alignment of the optics with the incident light and receiver.

In yet another embodiment, an internal tracker would be suitable for both seasonal and diurnal tracking whilst working in conjunction with the appropriate rotation about the tilt axis.

### Mirror and Lens Manufacturability

With modern machining capabilities, it is possible to manufacture freeform surfaces such as the ones in this design. The primary optic is an aspheric surface and is capable of being manufactured by slow servo, diamond turning machines. For a small number of parts, it would be more practical to machine glass or plastic directly. However, on the large scale, a mold, typically made of aluminum, would have to be made and used for compression molding of glass or plastic.

For the mirrors, the surfaces lack any rotational symmetry and thus must be manufactured using a fast servo, diamond turning machine. Again, if only a few parts are needed they may be manufactured directly. However, a mold may be machined from aluminum or another suitable material if large scale production is required. Once the plastic part is made, its surface may be covered with a reflective coating to create a mirrored surface.

### Assembly

From an economic standpoint, it is very important that the module be very easy to manufacture and have as many similarities with conventional manufacturing techniques as possible in order to mitigate costs.

It is well known to those skilled in the art that the methods of manufacturing the present invention are numerous. The following description of a method of assembling made components is intended as a simple example and is in no way intended to limit the scope of the invention or how it may be manufactured.

The lens array may make use of a single substrate with the lenses molded into it. The module box may be made with a single sheet of metal, or another suitable material, which may be folded and cut to attain the desired shape. The optical components, besides the lenses within the lens array, may be manufactured using glass compression molding, injection molding, thermal slumping, or some other suitable method. The numerous optical components would be assembled and fixed to the module box using massively parallel assembly methods. Parallel assembly may also allow the use of very small cells which are on the order of 1 cm² or smaller whilst remaining economical. The use of smaller cells may also allow for thermal management which requires a very small heat sink, and where the module box may serve as the heat sink.

### CPV Systems

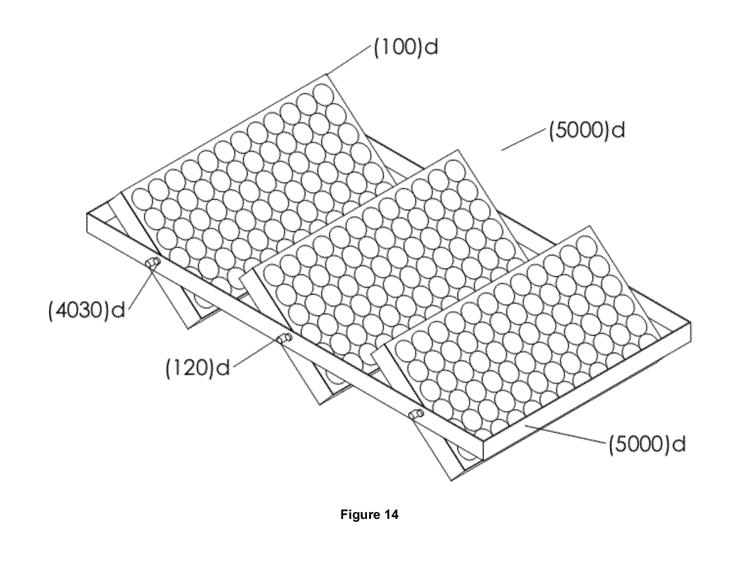

In a preferred embodiment, shown in FIG. 14, we have a louvered system (5000)d comprising, a frame (5000)d made such that one or more modules (100)d may be mounted rotatable on the frame (5000)d, such that an actuator (4030)d may rotate the module (100)d about a pivot (120)d.

A louvered system (5000)d may be mounted onto any manmade structure, such as an inclined roof, or such as a wall, or such as a parking lot canopy.

Another preferred use of the invention is for solar tracking wherein the module is mounted to a racking system placed on the ground.

One preferred use of the invention is for solar tracking wherein the module is mounted to a building, a parking lot canopy, or some other man made structure built for some use other than just holding the solar tracker.

The system may be integrated into the structure to add both functional and aesthetic value to the structure. And the tilt axis about which the module rotates may preferably be substantially horizontal at locations within 20° latitude from the equator; substantially vertical for locations above 30° latitude; at a tilt substantially equal to the latitude in which it is located; or at an angle that allows the module to optimally fulfill both its power generating function, aesthetic appeal, and other possible secondary functions.

The module may also be mounted so that it may rotate by 360° about the tilt axis such that when a reverse bias is applied to the photovoltaic cell receiver, luminescent light is directed towards an object that is desired to be illuminated. There may also be an auxiliary device mounted within the module to produce light which is directed by the optical module towards an object that is desired to be illuminated.

### Off-Angle Tracking Detailed Description

The following discussion is not intended to limit the scope of the invention in anyway. Rather, it is only intended for clarification of off-angle tracking concept within the context of solar tracking. It is also clear to those skilled in the art that that the reference geometry in no way limits the function of any physical embodiments of the off-angle tracking concept. As is obvious to those skilled in the art, it only serves as an abstraction used to clarify how physical embodiments are intended to function. This description is self contained, but it is also a natural extension to descriptions of conventional tracking seen in literature.
“Chong, K. K. & Wong, C. W., 2009. General formula for on-axis sun-tracking system and its application in improving tracking accuracy of solar collector. Solar Energy, 83(3), pp. 298-305.”
“Sproul, A. B., 2007a. Derivation of the solar geometric relationships using vector analysis. Renewable Energy, 32(7), pp. 1187-1205.”

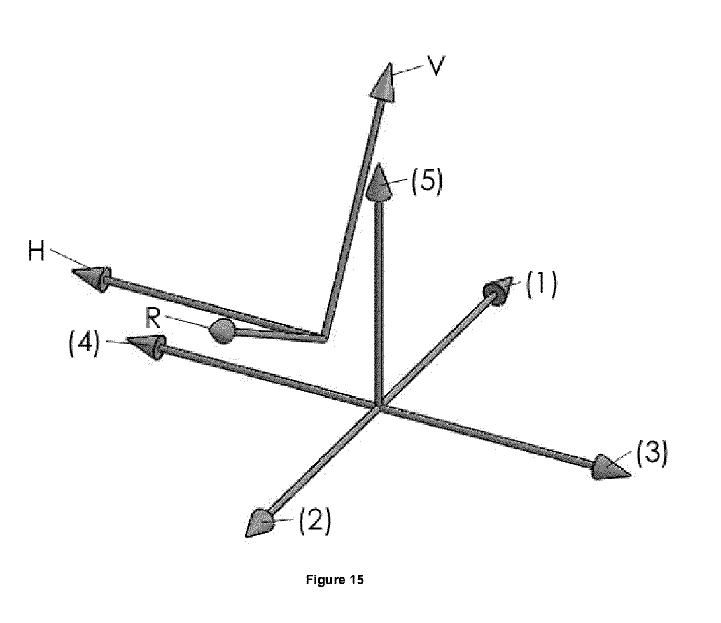

Before deriving a mathematical representation of off-angle tracking, a reference frame needs to be established. Conventional tilt-roll trackers can be described quite simply within the collector reference frame which is defined by the horizontal axis, H, the reference axis, R, and the vertical axis, V. The collector reference frame orientation, as seen in FIG. 15, is made with respect to the Earth surface reference frame defined by the compass directions, north (1), south (2), east (3) and west (4), and the zenith (5). The collector reference frame is oriented such that V is both aligned with the Earth's axis of rotation and points towards the celestial north pole; H points westward; and R is orthogonal to them both. As known to those skilled in the art, this orientation requires that the angle of V with respect to the zenith is approximately equal to π/2 minus the latitude of the collector reference frame's location on Earth.

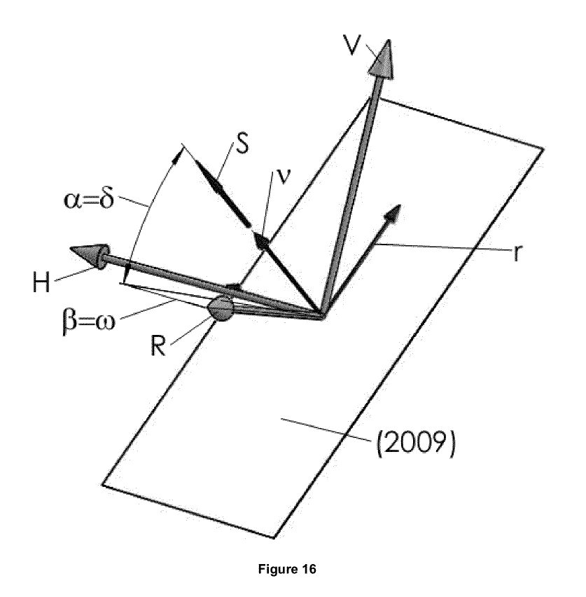

As seen in FIG. 16, the tracker orientation within the collector reference frame is defined by the position of the collector plane normal, v, the collector plane vector, k, and the tilt axis vector, r. Collectively, these three vectors are referred to as the collector plane's reference frame. The collector plane (2009) is a visual representation of how the surface of some module described in previous embodiments should be oriented. And it should be noted that all vectors in this discussion are considered to be unit vectors unless otherwise stated.

In regards to the tracker orientation for a dual axis, tilt-roll system, the movement of the tracker is restricted such that k always remains within the plane formed by H and R. With the remaining two degrees of freedom, v is oriented according to the angle beta, β, and angle alpha, α. To align v with the Sun's position vector, S, one must set β equal to the hour angle, ω, and α, equal to the declination, δ.

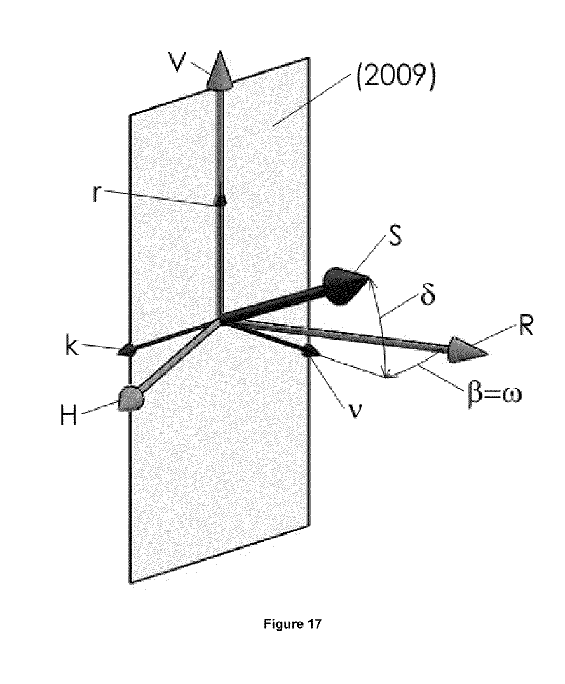

In the case of the polar aligned single axis tracker, as seen in FIG. 17, r remains coincident with V, which forces the angle α to be zero. With the remaining degree of freedom, v is positioned such that β equals ω. Thus, in this case a change in S always remains within the plane occupied by v and V. Then the angle S makes with respect to v is equal to δ.

Now, it will be shown that by simply shifting the diurnal motion of the single axis tracker by a phase shift, ψ, such that β=ω+ψ, then a constant off-angle, κ, can be made between S and v.

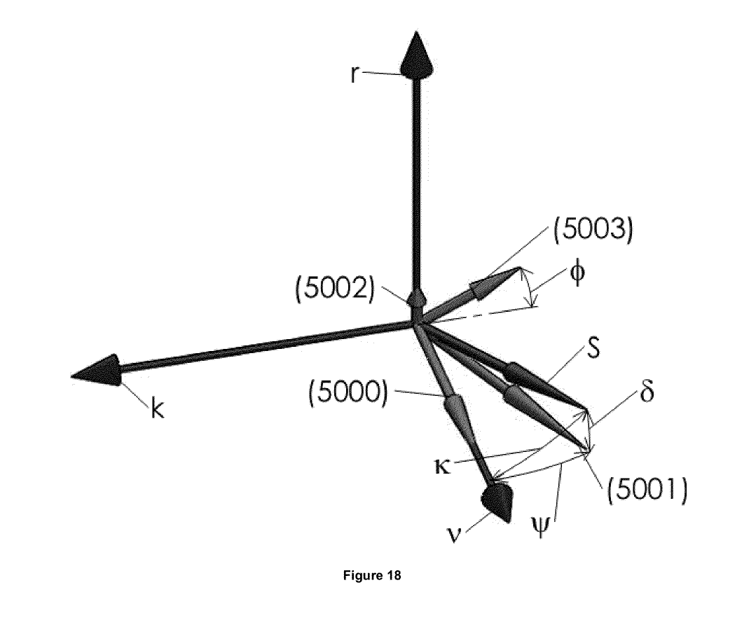

Consider only the collector plane's reference frame which is only allowed to rotate about r such that S remains at an off-angle, κ, with respect to v. As seen in FIG. 18, the consequence is that the projection of S on v, projection (5000), has a magnitude cos(K); the projection of S on the k-v plane, projection (5001), has a magnitude cos(δ); the projection of S on r, projection (5002), has a magnitude sin(δ); and lastly, the projection of S on the k-r plane, projection (5003), has a magnitude of sin(K).

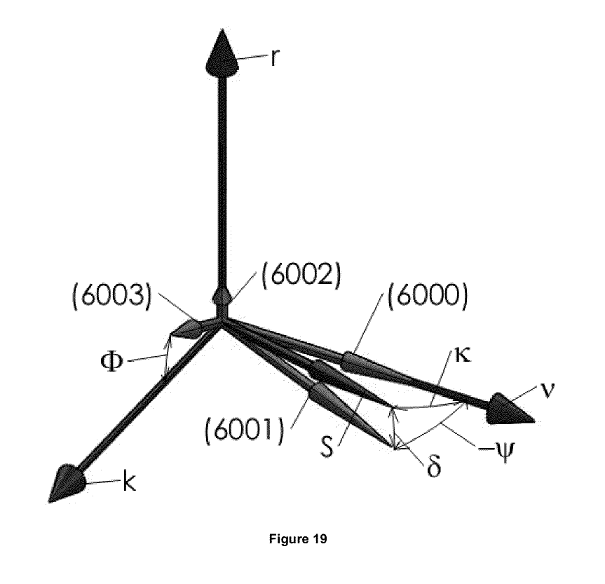

As is clear to those in the art, one may also subtract ψ from ω to achieve an angle κ between S and v. As seen in FIG. 19, the consequence is that the projection of S on v, projection (6000), has a magnitude cos(K); the projection of S on the k-v plane, projection (6001), has a magnitude cos(δ); the projection of S on r, projection (6002), has a magnitude sin(δ); and lastly, the projection of S on the k-r plane, projection (6003), has a magnitude of sin(K).

It follows, therefore, that if one wants to move v with respect to S subject to our declared constraints, the following relationships must also be true.

$$\begin{matrix}cos ( ψ ) = \frac{cos ( κ )}{cos ( δ )} \\ And , & ( 1 ) \\ sin ( φ ) = \frac{sin ( δ )}{sin ( κ )} & ( 2 )\end{matrix}$$

Where we define,

0<κ (3)

Equation (1) and (2) provide us with the transformation from conventional polar tracking to an off-axis tracking configuration given κ and δ. As the naming convention implies, the phase shift, +ψ, is simply a shift of the diurnal tracking motion from the hour angle w. As seen in FIG. 18, the alignment angle, φ, is the angle of projection (5003), with respect to the negative of k. It indicates how components, with which some optical module is comprised of, must be oriented. Exactly how these components are oriented depends on the exact design, and should be obvious to those skilled in the art. In any case, something with which the optical module is comprised of, must undergo some form of dynamic change that leads to a change in symmetry about the spin axis by an amount proportional to the change in φ.

There are clearly two possible scenarios corresponding to +ψ, which clearly satisfies the conditions in Equation (1) since cos(ψ) and cos(−ψ). As illustrated in FIG. 18, when we add a phase shift, ψ, then φ must be measured with respect to the negative of k. Using the same type of reasoning, we refer to FIG. 19 and see that when ψ is subtracted from ω, the alignment angle φ must be measured with respect to k. Besides the axis from which φ is measured, it can be treated exactly the same as φ.

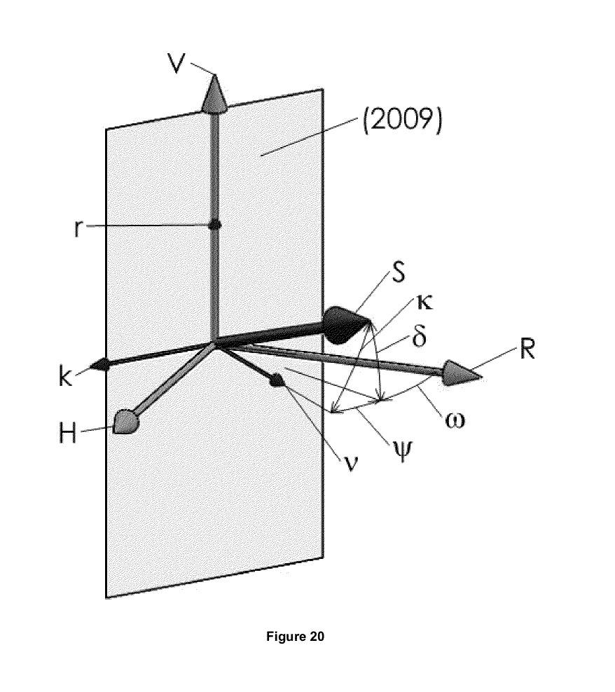

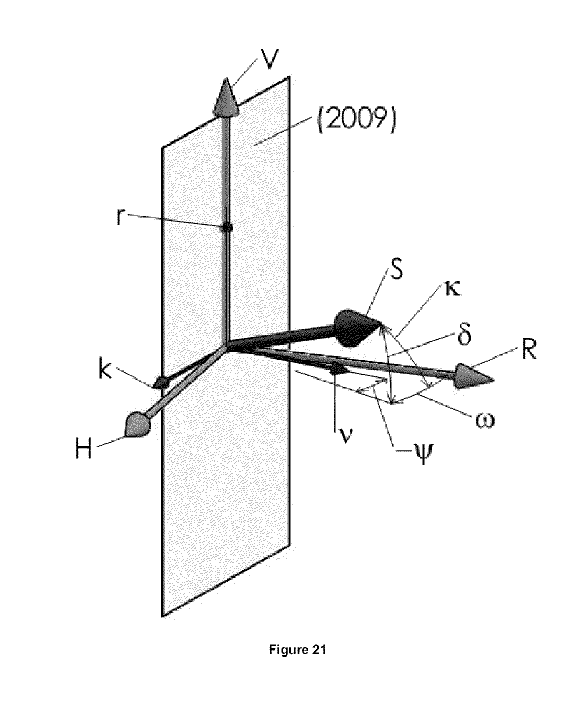

To clarify the diurnal motion of an off-angle tracker, the orientation of the collector plane normal with respect to the collector frame of reference is shown in FIG. 20 and FIG. 21 with the orientation of the collector plane normal set to be at β=ω+ψ and β=ω−ψ respectively.

Within the context of solar tracking, off-angle tracking works because the source position is always between the winter and summer solstice. Unlike conventional tracking, off-angle tracking is not capable of aligning the optics at any point within 4π stredian and this can be understood by observing Equation (1) where we can clearly see that if K<|δ|, the equation has no real solution.

Physically, this requirement means that in order for off-angle tracking to be possible, δ must never exceed K. In a more abstract sense, an imaginary belt, symmetrical about the R-H plane and with an angular extent −κ<δ<κ, may define the region where S may point to while satisfying the conditions set forth by Equation (1) and (2).

It should be emphasized that the off-angle tracking concept is not limited to a specific orientation of the collector reference frame in the context of solar tracker. It is possible, and in some cases may be more practical not to align the vertical axis, V, with respect to the Earth's axis of rotation. In addition, this collector reference frame is intended for clarification of the off-angle tracking concept application to solar tracking. But the invention is in no way limited to tracking a light source which is the Sun.

What is claimed is:

1. A light tracking module comprising:
a) an optical module which is configured to rotate about a tilt axis so that incident light remains at an off angle with respect to a spin axis;
b) and the optical module is configured so that the incident light at the off angle with respect to the spin axis is transformed into converging light incident on a receiver.

2. The optical module of claim 1 wherein the optical module comprises:
a) a lens comprising a curved surface that is facing the incident light and is rotationally symmetric about the spin axis,
b) where the lens focuses the incident light onto an outer mirror placed away from the spin axis,
c) the outer mirror focuses light from the lens onto an inner mirror substantially centered on the spin axis,
d) the inner mirror transforms light from the outer mirror into the converging light incident on the receiver.

3. The outer mirror and the inner mirror of claim 2 wherein each have symmetry about the same meridional plane of the lens.

4. The optical module of claim 3 wherein the inner mirror and the outer mirror are fixed to a rotatable mount.

5. The optical module of claim 1 wherein the optical module comprises:
a) the lens comprising a curved surface that is facing the incident light and is rotationally symmetric about the spin axis,
b) the lens focuses the incident light onto the receiver placed away from the spin axis.

6. The optical module of claim 5 wherein the orientation of the receiver is such that the intensity distribution of light is substantially centered about the normal of the receiver surface.

7. The optical module of claim 6 wherein the receiver is fixed to a rotatable mount.

8. The optical module of claim 5 wherein the orientation of the receiver is such that the normal of the receiver is substantially parallel to the spin axis.

9. The optical module of claim 8 wherein the lens is part of a lens array that is moved in two linearly independent directions such that the lens travels a circular path around the respective spin axis.

10. The optical module of claim 1 wherein the receiver is a photovoltaic cell with a size between 0.1 mm² and 3 cm².

11. The optical module of claim 10 wherein concentration is between 100 to 2000 times.

12. The optical module of claim 1 wherein the optical module depth is no more than 30 cm.

13. The light tracking module of claim 1 wherein the off angle is between 20° and 30°.

14. A method of tracking the Sun comprising:
a) rotating a light tracking module about its tilt axis so that incident light is always at an off angle with respect to the normal of the light tracking module.

15. A method according to claim 14, wherein the off angle is equal to a constant value between 20 degrees and 30 degrees.

16. A method according to claim 15, wherein the off angle is equal to a constant value between 22 degrees and 25 degrees.

17. A concentrator photovoltaic system comprising,
one or more light tracking modules that may be fixed to a building, an inclined roof, a wall, a parking lot canopy, a rack, or any other man made structure.

18. The concentrator photovoltaic system of claim 17 wherein a tilt axis of the light tracking module is parallel within 10 degrees of the Earth's axis of rotation.

19. The concentrator photovoltaic system of claim 17 wherein the tilt axis is horizontal or vertical.

20. The light tracking module of claim 17 wherein the light tracking module may be rotated about the tilt axis by at least 360°.
